(19) United States
(12) Patent Application Publication
(10) Pub. No.: US 2018/0148827 A1
(43) Pub. Date: May 31, 2018

(54) THERMAL CONDUCTION DEVICE AND VAPOR DEPOSITION CRUCIBLE

(71) Applicant: Shenzhen China Star Optoelectronics Technology Co., Ltd., Shenzhen, City (CN)

(72) Inventors: Yang Liu, Shenzhen City (CN); Yawei Liu, Shenzhen City (CN)

(21) Appl. No.: 15/108,319

(22) PCT Filed: Apr. 25, 2016
(86) PCT No.: PCT/CN2016/080104

§ 371 Date: Jun. 27, 2016

(30) Foreign Application Priority Data
Mar. 16, 2016 (CN) 201610150210.8

(51) Int. Cl. C23C 14/24

(52) U.S. Cl. CPC C23C 14/243

(57) ABSTRACT

The present invention provides a thermal conduction device and a vapor deposition crucible, the thermal conduction device comprises a thermal conduction tube and several thermal conduction plates installed on the thermal conduction tube to be radiation-like, or shows radiation-like by comprising a radiation-like thermal conduction tube; by placing the thermal conduction device in the vapor deposition crucible, the heat on the wall of the crucible can be evenly conducted to inside and center of the crucible through the heat conduction path of the thermal conduction device, thus to enhance the heated uniformity of the material in the crucible, to stabilize the evaporation status of the material, to improve the effect of vapor deposition; besides, the thermal conduction device is easily machined, low cost, good thermal conductivity, and easy to install and remove.

### BACKGROUND OF THE INVENTION

### 1. Field of the Invention

The present invention relates to a display technology field, and more particularly to a thermal conduction device and a vapor deposition crucible.

### 2. The Related Arts

Organic light-emitting diode (OLED) display, also called organic electroluminescent display, is an emerging flat panel display device possessing advantages of simple preparation process, low cost, power saving, high brightness, wide operating temperature range, thin body, fast response, and easy to realize color display and large screen display, easy to realize matching with integrated circuit driver, easy to realize flexible display and so on, thus has broad application prospects. Current manufacturing technology in realizing volume production for OLED is all using vacuum vapor deposition method to prepare films for OLED.

In vacuum vapor deposition, a material for the OLED is placed in the crucible and the material is vaporized by heating, the vaporized molecules fly out from the nozzle of the crucible cover and form a solid film on the substrate by deposition. The material for the OLED are generally divided into a sublimation type and a melting type, the sublimation type material is sublimated to gaseous state directly from solid powder state by heating, the melting type material becomes melted state from solid powder state by heating, and then evaporated into gaseous state. The heat conductivity of the organic material for the OLED is generally poor whether it is a sublimation type or a melting type, and without gas molecules as a thermal conduction medium under vacuum condition, the heat transmission from the wall of the crucible to the center of the crucible is usually very slow, which causes a huge temperature difference in the crucible, that means a non-uniform temperature field is inside the crucible.

Wherein the sublimation type material, a non-uniform temperature field easily results in the status shown in FIG. 1: the portion of the material 200 close to the wall of the crucible 100 is at higher temperature and sublimates fast, and the portion of the material 200 away from the wall of the crucible 100 is at lower temperature and sublimates slowly. A gap 300 will be formed between the material 200 and the wall of the crucible 100 after certain period of sublimation, then the material 200 needs to be heated to a much higher temperature to achieve the sublimating speed after the gap 300 is formed, that is bad for the performance of the OLED.

Wherein the melting type material, a non-uniform temperature field easily results in the status shown in FIG. 2: the portion of the material 200 close to the wall of the crucible 100 reaches required temperature for melting first then becomes melted state, the portion of the material 200 away from the wall of the crucible 100 is still at solid powder state, then the portion of the material 200 in powder state is wrapped by the portion of the material 200 in melted state because the material 200 in melted state have certain fluidity, thus the whole material 200 is under “semi-melted state”, and the film uniformity deposited on the substrate by the material 200 under semi-melted state is bad, will result in a bad OLED performance.

### SUMMARY OF THE INVENTION

An object of the invention is to provide a thermal conduction device, that is placed and used inside a vapor deposition crucible, can evenly conduct the heat from the wall of the crucible to the inside and center of the crucible, and then a material inside the crucible is uniformly heated.

The other object of this invention also provides a vapor deposition crucible, which will evenly conducts the heat on the wall of the crucible to the inside and center of the crucible, and enhances the heated uniformity of the material in the crucible.

For realizing the aforesaid objective, the present invention provides a thermal conduction device comprising a thermal conduction tube and several thermal conduction plates installed on the thermal conduction tube, wherein several holes are arranged on a sidewall of the thermal conduction tube and also on the thermal conduction plate.

Wherein several strip type grooves are arranged between the several holes located on the sidewall of the thermal conduction tube, and extending directions of the strip type grooves are all parallel to an extending direction of the thermal conduction tube, the several thermal conduction plates are respectively wedged in the several strip type grooves.

A cross section of the thermal conduction tube is a circle or an axially symmetric convex polygon.

A material of the thermal conduction tube and the thermal conduction plate is metal.

he present invention also provides a thermal conduction device comprising a thermal conduction tube, a cross section of the thermal conduction tube is a star with three or more corners, and each corner of the star is enclosed by two pieces of the thermal conduction plates, thus the thermal conduction tube is composed by six or more pieces of the thermal conduction plates in an interconnected condition, wherein several holes are arranged on each thermal conduction plate

The present invention also provides a vapor deposition crucible comprising a crucible body, a thermal conduction device placed inside the crucible body, and a crucible cover located above the crucible body. The thermal conduction device comprises a thermal conduction tube and several thermal conduction plates installed on the thermal conduction tube, wherein several holes are arranged on a sidewall of the thermal conduction tube and the thermal conduction plate.

Wherein several strip type grooves are arranged between the holes on the sidewall of the thermal conduction tube, and extending directions of the several strip type grooves are all parallel to an extending direction of the thermal conduction tube, the several thermal conduction plates are respectively wedged in the several strip type grooves.

A cross section of the thermal conduction tube is a circle or an axially symmetric convex polygon.

A height of the thermal conduction device is less than a height of an inner space of the crucible body; a radial dimension of the thermal conduction device is less than a radial dimension of the inner space of the crucible body.

The present invention also provides a vapor deposition crucible comprising a crucible body, a thermal conduction device placed inside the crucible body, and a crucible cover located above the crucible body. The thermal conduction device comprises a thermal conduction tube, a cross section of the thermal conduction tube is a star with three or more corners, and each corner of the star is enclosed by two pieces of the thermal conduction plates, thus the thermal conduction tube is composed by six or more pieces of the thermal conduction plates in an interconnected condition, wherein several holes are arranged on each thermal conduction plate.

The benefits of the present invention are: the present invention provides a thermal conduction device and a vapor deposition crucible. The thermal conduction device comprises a thermal conduction tube and several thermal conduction plates installed on the thermal conduction tube is then radiation-like, or is radiation-like by comprising a radiation-like thermal conduction tube, wherein the thermal conduction device is placed in the vapor deposition crucible, the heat on the wall of the crucible is evenly conducted to the inside and center of the vapor deposition crucible through a heat transfer path of the thermal conduction device, and to enhance a heated uniformity of the material in the crucible, and to stabilize evaporating status of the material, and to improve the effect of vapor deposition; Besides, the thermal conduction device is easily machined, low cost, good thermal conductivity, and easy to install and remove.

In order to further understand the features and technical contents of the present invention, please reference below for a detailed description of the invention and drawings, drawings provide for reference and explanation only, however are not used to limit the invention.

### BRIEF DESCRIPTION OF THE DRAWINGS

Combining with drawings below and detailed descriptions for specific embodiments of the present invention, then the technical solutions and other benefits of the present invention are obviously.

In drawings,

FIG. 1 is a diagram of sublimation type material in a current vapor deposition crucible, a gap is formed according to a non-uniformly heating;

FIG. 2 is a diagram of melting type material in a current vapor deposition crucible, a semi-melted state is formed according to non-uniformly heating;

FIG. 3 is a structure diagram of a first embodiment of the thermal conduction device of the present invention;

FIG. 4 is a structure diagram of a second embodiment of the thermal conduction device of the present invention;

FIG. 5 is a sectional diagram of a third embodiment of the thermal conduction device of the present invention, and a diagram of a piece of thermal conduction plates, that composing the thermal conduction tube;

FIG. 6 is a sectional diagram of a forth embodiment of the thermal conduction device of the present invention, and a diagram of a piece of thermal conduction plates, that composing the thermal conduction tube; and

FIG. 7 is a structure diagram of a vapor deposition crucible of the present invention.

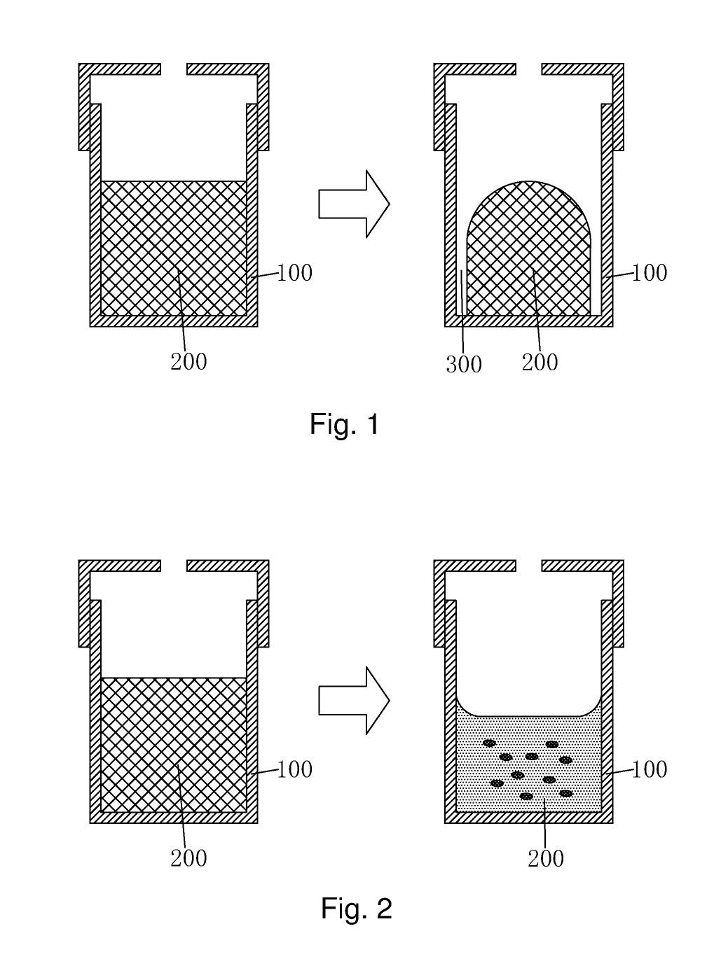

### DETAILED DESCRIPTION OF THE PREFERRED EMBODIMENTS

For further elaborating the technical solution in present invention and the effect, the present invention will be further described in detail with specific embodiment and attached drawings.

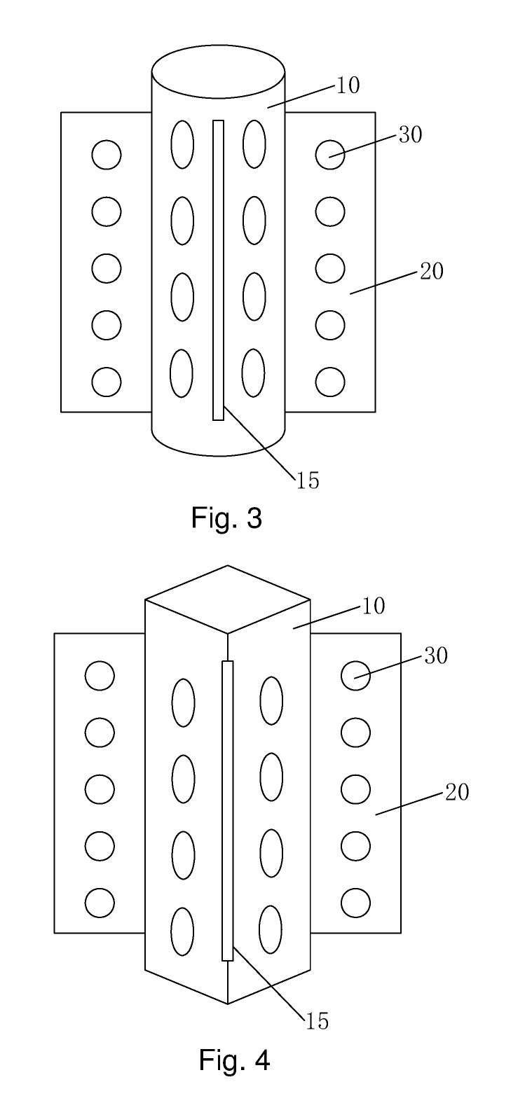

Please refer to FIGS. 3 and 4, the present invention provides a thermal conduction device, placed and used in a vapor deposition crucible, comprising a thermal conduction tube 10 and several thermal conduction plates 20 installed on the thermal conduction tube 10, wherein several holes 30 are arranged on a sidewall of the thermal conduction tube 10 and on the thermal conduction plate 20, the hole 30 can make a material in the vapor deposition crucible flowing and link together, and to enhance a thermal conduction uniformity inside the crucible.

Specifically, a cross section of the thermal conduction tube 10 is an axially symmetrical pattern, and to enhance the thermal conduction uniformity.

Specifically, a cross section of the thermal conduction tube 10 can be a circle, or can be an axially symmetric convex polygon, for example a isosceles triangle, an equilateral triangle, a rectangle, a square and so on; wherein the first embodiment of the thermal conduction device shown in FIG. 3, a cross section of the thermal conduction tube 10 is a circle; wherein the second embodiment of the thermal conduction device shown in FIG. 4, a cross section of the thermal conduction tube 10 is a square.

Specifically, several strip type grooves 15 are arranged between the several holes 30 located on a sidewall of the thermal conduction tube 10, and extending directions of the several strip type grooves 15 are all parallel to an extending direction of the thermal conduction tube 10, the several thermal conduction plates 20 are respectively wedged in the several strip type grooves 15, then installed on the thermal conduction tube 10, and an installation method is easy to remove.

Preferably, the several strip type grooves 15 are uniformly distributed on the sidewall of the thermal conduction tube 10, thus the several thermal conduction plates 20 are uniformly located around the thermal conduction tube 10, then to enhance the uniformity of the heat transmission of the thermal conduction device.

The first thermal conduction device shown in FIGS. 3 and 4, wherein the thermal conduction device is radiation-like through installing the several thermal conduction plates 20 around the thermal conduction tube 10, then to enhance the uniformity the heat transmission.

Specifically, a pattern of the hole 30 can be a circle, a rectangle, a triangle, a convex polygon, a star and so on. Preferably, the several holes 30 located on the sidewall of the thermal conduction tube 10 are uniformly distributed, and are the same pattern and size, and the several holes 30 located on the thermal conduction plate 20 are uniformly distributed, and are the same pattern and size.

Specifically, a material of the thermal conduction tube 10 and the thermal conduction plate 20 is generally metal, for example titanium alloy, aluminum alloy, stainless steel and so on.

When the aforesaid thermal conduction device is placed in the vapor deposition crucible, the heat on the wall of the crucible can be evenly conducted to the inside and center of the vapor deposition crucible through a heat transfer path of the thermal conduction tube 10 and the thermal conduction plate 20, and then improves a heated uniformity of the material in the crucible, thus to stabilize a evaporation status of the material and to improve the effect of vapor deposition; besides, the thermal conduction device is easily machined, low cost, good thermal conductivity, and easy to install and remove.

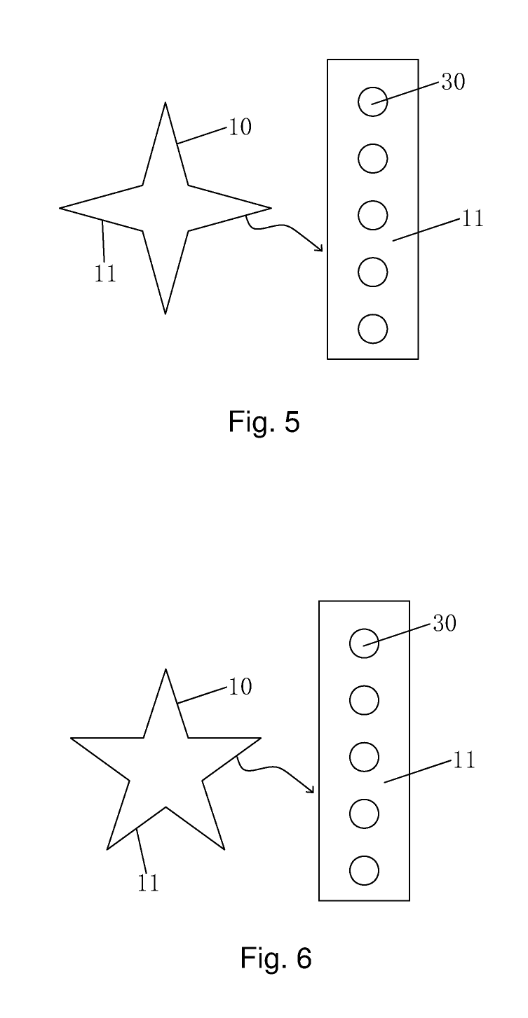

Please refer to FIGS. 5 and 6, the present invention also provides a thermal conduction device placed in the vapor deposition crucible comprising a thermal conduction tube 10, a cross section of the thermal conduction tube 10 is a star with three or more corners, and each corner of the star is enclosed by two pieces of the thermal conduction plates 11, thus the thermal conduction tube 10 is composed by six or more pieces of the thermal conduction plates 11 in an interconnected condition, wherein several holes 30 are arranged on each thermal conduction plate 11, that make the material inside the vapor deposition crucible flowing and link together; a third embodiment of the thermal conduction device shown in FIG. 5, the cross section of the thermal conduction tube 10 is a star with four corners; a forth embodiment of the thermal conduction device shown in FIG. 6, the cross section of the thermal conduction tube 10 is a star with five corners; wherein the second thermal conduction device, it can realize a good uniformity of thermal conduction without installing the thermal conduction plates around the thermal conduction tube 10 because the thermal conduction tube 10 is itself radiation-like.

Specifically, the several thermal conduction plates 11 to compose the thermal conduction tube 10 can be integrated molding, can be fixed and attached together by welding or other methods, even can be composed together by a movable and detachable method.

Specifically, a cross section of the thermal conduction tube 10 is an axially symmetrical pattern, and to enhance a good uniformity of thermal conduction.

Specifically, a material of the thermal conduction tube 10 is generally a metal, for example a titanium alloy, an aluminum alloy, a stainless steel and so on.

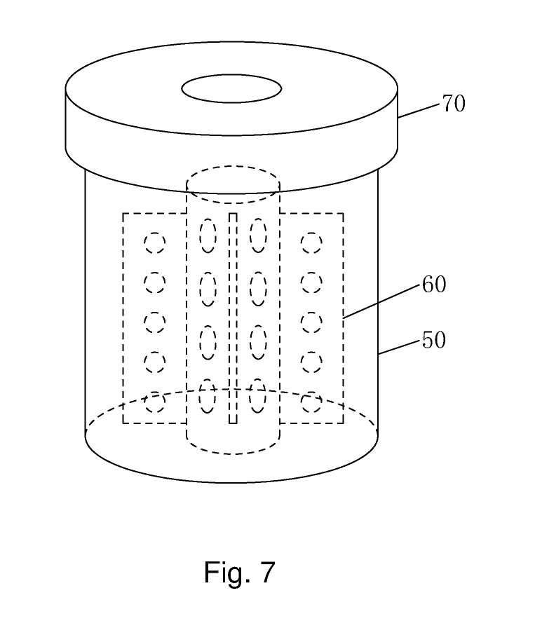

For further, please refer to FIG. 7, combining with FIG. 3 to FIG. 0.6, the present invention also provides a vapor deposition crucible comprising a crucible body 50, a thermal conduction device 60 placed in the crucible body 50, a crucible cover 70 located above the crucible body 50, the thermal conduction device 60 can be the first thermal conduction device shown in the FIGS. 3 and 4, or the second thermal conduction device shown in the FIGS. 5 and 6.

Specifically, a height of the thermal conduction device 60 is less than a height of an inner space of the crucible body 50; an axial dimension of the thermal conduction device 60 is less than an axial dimension of an inner space of the crucible body 50.

In conclusion, the present invention provides a thermal conduction device and a vapor deposition crucible, the thermal conduction device comprises a thermal conduction tube and several thermal conduction plates then to be radiation-like, or shows radiation-like by comprising a radiation-like thermal conduction tube, wherein the aforesaid thermal conduction device is placed in the vapor deposition crucible, heat on the wall of the vapor deposition crucible will be evenly conducted to the inside and center of the crucible through the heat conduction path of the thermal conduction device, thus to enhance the heated uniformity of the material in the crucible, to stabilize the evaporation status of the material, to improve the deposition result; besides, the thermal conduction device is easily machined, low cost, good heat conductivity, and easy to install and remove.

Above are only specific embodiments of present invention, the scope of the present invention is not limited to this, and to any persons who are skilled in the art, change or replacement which is easily derived should be covered by the protected scope of the invention. Thus, the protected scope of invention should go by the subject claims.

What is claimed is:

1. A thermal conduction device, comprising a thermal conduction tube and several thermal conduction plates installed on the thermal conduction tube, wherein several holes are arranged on a sidewall of the thermal conduction tube and the thermal conduction plate.

2. The thermal conduction device according to claim 1, wherein several strip type grooves are arranged between the holes located on the side wall of the thermal conduction tube, extending directions of the several strip type grooves are all parallel to an extending direction of the thermal conduction tube, the several thermal conduction plates are respectively wedged in the several strip type grooves.

3. The thermal conduction device according to claim 1, wherein a cross section of the thermal conduction tube is a circle or an axially symmetric convex polygon.

4. The thermal conduction device according to claim 1, wherein a material of the thermal conduction tube and the thermal conduction plate is metal.

5. A thermal conduction device, comprising a thermal conduction tube, a cross section of the thermal conduction tube is a star with tree or more corners, each corner of the star is enclosed by two pieces of the thermal conduction plates, thus the thermal conduction tube is composed by six or more pieces of the thermal conduction plates in an interconnected condition, wherein several holes are arranged on each of the thermal conduction plate.

6. A vapor deposition crucible, comprising a crucible body, a thermal conduction device placed in the crucible body, and a crucible cover located above the crucible body; the thermal conduction device comprises a thermal conduction tube and several thermal conduction plates installed on the thermal conduction tube, wherein several holes are arranged on a sidewall of the thermal conduction tube and also on the thermal conduction plate.

7. The vapor deposition crucible according to claim 6, wherein several trip type grooves are arranged between the several holes on the sidewall of the thermal conduction tube, extending directions of the several strip type grooves are all parallel to an extending direction of the thermal conduction tube, the thermal conduction plates are respectively wedged in the several strip type grooves.

8. The vapor deposition crucible according to claim 6, wherein a cross section of the thermal conduction device is a circle or an axially symmetric convex polygon.

9. The vapor deposition crucible according to claim 6, wherein a height of the thermal conduction device is less than a height of an inner space of the crucible body, an axial dimension of the thermal conduction device is less than an axial dimension of an inner space of the crucible body.

10. A vapor deposition crucible, comprising a crucible body, a thermal conduction device placed in the crucible body, and a crucible cover located above the crucible body; the thermal conduction device comprises a thermal conduction tube, a cross section of the thermal conduction tube is a star with three or more corners, each corner of the star is enclosed by two pieces of the thermal conduction plates, thus the thermal conduction tube is composed by six or more pieces of the thermal conduction plates in an interconnected condition, wherein several holes are arranged on each thermal conduction plate.
